(19) United States
(12) Patent Application Publication
(10) Pub. No.: US 2005/0195194 A1
(43) Pub. Date: Sep. 8, 2005

(54) 3-D eye diagram

(76) Inventor: Alan K. Cummings, Austin, TX (US)

Correspondence Address: Jeffrey C. Hood;Meyertons, Hood, Kivlin, Kowert & Goetzel PC, P.O. Box 398, Austin, TX, 78767, US

(21) Appl. No.: 10/795,762

(22) Filed: Mar. 8, 2004

(51) Int. Cl. H03F 3/04

(52) U.S. Cl. 345/440

(57) ABSTRACT

System and method for analyzing signals. Signal data corresponding to a signal is received, e.g., from a data acquisition device, and processed to generate formatted signal data, including segmenting the signal data based on the a period of the signal data to generate segments. The formatted signal data is displayed in a three dimensional (3D) eye diagram by plotting the segments in an overlaid manner, which is usable to analyze the signal. User input may be received specifying attributes of the 3D eye diagram, e.g., zoom, rotation, translation, stereoscopy, display device, plot colors and line styles, point colors and styles, symbol rate, eye length, number of segments to display, projections, e.g., for generating I- or Q-eye diagrams or constellation diagrams, auxiliary information display, e.g., highlight points for symbol timing and/or additional points for ideal symbol locations, data sources, etc., and the 3D eye diagram displayed according to the specified attributes.

### FIELD OF THE INVENTION

The present invention relates to a system and method for performing signal analysis. More particularly, a system and method for creating and using a three dimensional (3D) eye diagram to display and analyze data associated with data and communication signals is presented.

### DESCRIPTION OF THE RELATED ART

Signal communications have become central to many aspects of the modern world. In fact, virtually all modern business, manufacturing, engineering, and scientific enterprises rely substantially on signal communications to perform their activities. To support this ubiquitous phenomenon, a vast and varied technological infrastructure has been, and continues to be, developed, including wireless and wired telecommunications media, fiber-optic components, routers, transmitters, analog and digital signal processing chips, and myriad software programs for managing, processing, analyzing, and transmitting these signals, among others. These communications related components generally require testing and diagnostic analysis to ensure proper behavior and/or design, as well as calibration and tuning for particular applications.

Traditionally, Radio Frequency (RF) signals have been viewed as two component signals that vary with time: the In-Phase (I) component and the Quadrature (Q) component. In digitally modulated RF signals, the concepts of a symbol rate and symbol period (where the rate is the inverse of the period) are used to characterize signals. In digitally modulated signals, an underlying discrete (digital) signal is periodically updated to the next value. This period is the symbol period. However, the transmitted/received signal is typically filtered, and so this periodicity may not be readily apparent.

There are numerous traditional ways of viewing and analyzing these signals, including, for example, I (or Q) vs. time diagrams, I vs. Q diagrams, eye diagrams, constellation diagrams, trellis diagrams, and I vs. Q vs. time diagrams. Each of these visualization tools provides different benefits for the analysis of signals.

FIG. 1 is an example of an I vs. time diagram, according to the prior art. This type of diagram can be used for viewing and analyzing analog or digital signals. In this example, the signal is a Quadrature Phase Shift Keyed (QPSK) signal, where QPSK refers to a form of digital modulation. Note that a Q vs. time diagram would look substantially the same, but with Q values rather than 1 values plotted vs. time.

FIG. 2 illustrates an I vs. Q vs. time diagram, according to the prior art. This particular form of 3D plot for complex signals has been patented (U.S. Pat. No. 6,377,260), and is effectively a combination of the two forms of the diagram of FIG. 1, i.e., I vs. time and Q vs. time. The patented form specifies that time is displayed along the Z axis. The plot of FIG. 2 is similar to the patented form of display, except time is plotted along the X axis. This plot also includes projections of the complex signal onto the X-Y and X-Z planes. These projections are equivalent to plots described above with reference to FIG. 1. The signal shown plotted in FIG. 2 is a Minimum Shift Keyed (MSK) signal.

FIG. 3 is an example of an I vs. Q diagram, according to the prior art. This type of diagram is also suitable for viewing and analyzing analog or digital signals, and, as the name implies, plots values of Q against values of I. In this example, the signal is a QPSK signal.

FIG. 4 illustrates a constellation diagram, according to the prior art, which is similar to an I vs. Q plot, but with signal points at the symbol timing highlighted or shown exclusively. In the plot of FIG. 4, a QPSK signal is shown in a constellation plot. The white points are the constellation points. The plot lines are equivalent to the I vs. Q plot in FIG. 3, described above.

FIG. 5 illustrates an example eye diagram, according to the prior art. Eye diagrams are typically only used for digitally modulated signals, and are a common way to analyze the performance of high-speed communication systems. In fact, eye diagrams are primary tools for interactive digital communication analysis. Eye diagrams are typically generated by transmitting random digital communication signals into a communication medium (optical fiber, co-axial cable, air/wireless, etc.) and sampling the output, e.g., on a high-speed sampling oscilloscope or similar instrument. Generally, a single component, e.g., I or Q, is divided into equally sized segments, where the size of the segments is an integer multiple of the symbol period. All of the segments are plotted overlaid on top of each other.

An eye diagram is useful for visualizing the underlying periodicity in an apparently random signal. As may be seen in FIG. 5, at particular periodic times the signal takes on discrete values. This set of times is called the symbol timing. At times other than the symbol timing, the value of the signal may appear random. The resulting pattern is the jittered digital pattern signals superimposed on each other. Over successive sweeps, the random bit patterns build up a composite picture of all the possible pattern sequences and transitions (low to low, high to high, high to low, and low to high).

Through analysis of an eye diagram image one may determine network and communication variables such as jitter, noise, pulse degradation, and intersymbol interference, among others. Eye diagram analysis may also facilitate mask testing. Specific parameters that can be determined from the eye diagram include, but are not limited to, extinction ratio, eye height, eye width, signal to noise ratios and Q-factors, duty cycle, bit rate, rise times, fall times, and eye amplitude. The eye diagram of FIG. 5 is for a QPSK signal.

FIG. 6 illustrates a trellis diagram, according to the prior art, which is similar to an eye diagram, except the vertical axis is phase instead of I or Q. The phase of the signal is the angle relative to the I axis in an I vs. Q plot (see FIG. 3), and is equal to ArcTan(Q/I). The signal plotted in FIG. 6 is an MSK signal.

### SUMMARY OF THE INVENTION

Various embodiments of a system and method for displaying and analyzing signals are presented. Signal data corresponding to a signal may be received. The signal may be any type of signal amenable to analysis with an eye diagram. For example, the signal may comprise digital and/or analog signals. In a preferred embodiment, the signal comprises a communications signal. In one embodiment, the signal may comprise an optical communications signal, e.g., for testing optical communications components and devices.

The signal data may be received in a variety of ways. For example, in one embodiment, the signal data may have been previously received or generated, and stored on a host computer system, or on a second computer system coupled to the host system, and so receiving the signal data may simply include retrieving the signal data from memory. In one embodiment, the signal data may be received from a data acquisition device, e.g., from a DAQ device (e.g., a DAQ board). Thus, receiving the signal data may include receiving the signal data from a storage medium, e.g., of the host system or a memory medium coupled to the host system (e.g., a memory medium of the second computer system), and so forth. Thus, in one embodiment, the signal data may be received from an external system, e.g., over a network.

As is well known in the art, a DAQ device generally receives a signal and operates to digitize the signal, thereby producing signal data, which may then be stored and/or analyzed. Thus, the DAQ device may receive the signal from a signal source and generate the signal data which may then be received from the DAQ device (e.g., by the host computer system). As described above, the signal source may be any of various types of signal source. In a preferred embodiment, the signal source is a UUT (unit under test), e.g., a communications device or component. In one embodiment, the signal may be processed before being acquired by the DAQ device, e.g., by a filter or other signal-conditioning device. For example, in some testing applications for high-speed communications devices, e.g., in the GHz range, the signal may need to be frequency shifted prior to acquisition by the DAQ device. Thus, in one embodiment, receiving the signal data from the DAQ device may include an analog down converter receiving the signal and converting the signal to a frequency-shifted signal, the DAQ device receiving the frequency-shifted signal from the analog down converter and generating the signal data, and receiving the generated signal data from the DAQ device. For example, in a preferred embodiment, the analog down converter may receive the signal in a radio frequency (RF) range, and down convert the RF signal to an intermediate frequency (IR) range, which may then be received and digitized by the DAQ device.

The received signal data may then be processed to generate formatted signal data. More specifically, the received signal data may be processed or otherwise formatted for display in a 3D eye diagram. In a preferred embodiment, processing the received signal data may include segmenting the signal data based on a specified period to generate a plurality of segments.

Finally, the formatted signal data may be displayed in a 3D eye diagram, where the 3D eye diagram is usable to analyze the signal. For example, the formatted signal data may be displayed in the 3D eye diagram by plotting the segments in an overlaid manner. In one embodiment, the method may optionally include analyzing the 3D eye diagram to generate signal analysis results, and outputting the signal analysis results, e.g., to one or more of: a display device, a storage medium, and/or an external system over a network, among others.

As is well known to those skilled in the art, the signal analysis results may include one or more of rise time, fall time, jitter RMS (root mean square), jitter pp, period, frequency, positive/negative pulse width, duty cycle, duty cycle distortion, delta time, extinction ratio, average power, crossing percentage, one/zero levels, eye height, width, and amplitude, Q-factor, bit rate, opening factor, and contrast ratio, among others.

In various embodiments, the systems and methods described herein may be implemented on or performed by various platforms, including, for example, computers, e.g., with one or more processors, memory, monitor, etc., as well as embedded systems, programmable hardware elements, such as FPGAs, and so forth.

The 3D eye diagram may be used to display various types of signal, such as, for example, QPSK signals, π/4 DQPSK signals, QAM signals, etc., among others. For example, in one embodiment, the 3D eye diagram may plot I (In-Phase) and Q (Quadrature) vs. time (I vs. Q vs. time), e.g., where the signal data corresponds to a QPSK signal.

There are numerous ways the 3D eye diagram may be useful for signal analysis. For example, the 3D eye diagram may be projected onto various 2D planes to generate respective 2D diagrams, e.g., a projection of the I vs. Q vs. time 3Deye diagram data onto the I-time plane. Note that this projection generates an I eye diagram, where I is plotted vs. time. A similar 2D eye diagram for Q may be generated by projecting the 3D eye diagram data onto the Q-time plane, where Q is plotted vs. time. Thus, the 3D eye diagram may be used, e.g., via projection, to generate standard 2D eye diagrams, whose use in signal analysis is well known in the art. Further projections of the 3D eye diagram may also be useful. For example, the 3D eye diagram data may be projected onto the I-Q plane, thereby generating an I vs. Q diagram, also referred to as a constellation plot, which is useful for signal analysis, as is also well known in the art. Note that in some embodiments, the projections may be performed simply by orienting the 3D eye diagram such that the displayed image of the 3D diagram comprises the desired projection. In other words, the 3D eye diagram may be manipulated to display or generate signal data and/or relationships that may be useful in analyzing the signal.

In standard (2D) eye diagrams, it is sometimes useful to indicate additional information in plots. For example, lines and/or points may be added to indicate ideal symbol timing locations, i.e., computed values of communications symbol starts and stops. Thus, in one embodiment, the 3D eye diagram may include auxiliary graphical elements indicating such ideal symbol locations, where the locations may be indicated with lines that intersect at the ideal points, as well as, for example, small points or spheres (or equivalent) at the ideal points. Of course, this is only one example of auxiliary information that may be added to the 3D eye diagram for analysis, and it should be noted that any other type of information may be included in the 3D eye diagram (or in plots or projections derived from the 3D eye diagram) as desired. Note that in one embodiment, the display (the 3D eye diagram) may also be used as a visual measure of the quality of a modulated signal, in that as the quality of the signal degrades, the nearest approach of the plots to the ideal symbol locations becomes progressively larger, i.e., the signal traces or plots “miss” the ideal locations by increasingly greater amounts.

As noted above, the utility of a 3D eye diagram may be substantially enhanced by manipulating the diagram, e.g., by changing the view angle, projecting the diagram onto various planes, adding auxiliary information, and so forth. Thus, in one embodiment, a graphical user interface (GUI) may be provided for specifying, creating, editing, and viewing 3D eye diagrams. Various embodiments of such a GUI or tool for 3D eye diagrams are described below. It should be noted that the embodiments described herein are intended to be exemplary only, and are not intended to limit the implementation, appearance, or functionality of the 3D eye diagram tool or GUI to any particular form.

In simple embodiments of the 3D eye diagram tool, the tool may primarily receive signal data, process the data as described above, and display the data in a 3D eye diagram, optionally allowing the user to rotate the diagram in 3D or otherwise project the diagram onto desired planes. Thus, the GUI may include a display area or panel for displaying the generated 3D eye diagram. However, in preferred embodiments, the 3D eye diagram tool may facilitate specification of many aspects of the diagram by the user. In other words, in a preferred embodiment, the method described above may include receiving user input specifying one or more attributes of the 3D eye diagram, and displaying the 3D eye diagram in accordance with the specified attributes.

For example, in one embodiment, specifying one or more attributes may include specifying one or more view parameters for displaying the 3D eye diagram, such as, for example, a zoom factor, a rotation of the 3D eye diagram, and a translation of the 3D eye diagram, thereby specifying an image of the 3D diagram. Thus, the user may specify an effective camera point of view (POV) and viewing distance (diagram size), for viewing the diagram. In various embodiments, the view parameters may be specified in different ways. For example, in one embodiment, the image may be “zoomed” using the mouse and/or keyboard. Similarly, rotations and translations may be specified using the mouse and/or keyboard. For example, in one embodiment, in one embodiment, the user may click on the diagram (e.g., on a “handle”, e.g., an axis endpoint, etc.) and, while holding the mouse key down, drag the mouse to rotate the diagram, where the direction of the mouse movement and/or the location of the diagram “handle” determines the axis of rotation. Alternatively, the user may specify an axis, then click on the diagram and, while holding the mouse key down, drag the mouse to rotate the diagram around the specified axis. In one embodiment, the user may use the mouse in combination with various keys to indicate the desired view specifications. Other means of zooming, rotating and translating the diagram are also contemplated. For example, in one embodiment, respective controls, e.g., slider controls, may be provided in the GUI for modifying zoom, rotation, and/or translation of the diagram.

In one embodiment, the user may manipulate the diagram (i.e., the image of the diagram) while the data are being acquired and/or displayed. Thus, the 3D eye diagram tool may be receiving and displaying signal data while the user modifies the display (or other aspects) of the diagram, where the display is updated in (substantially) real time in accordance with the modifications or specifications.

In one embodiment, specifying the one or more attributes may include specifying the one or more attributes based on a user-defined function, examples of which are given below.

In one embodiment, plot colors, plot line styles (e.g., line thickness, dotted, dashed, solid, etc.) and/or point color and/or styles, may be specified. For example, plot colors and/or line styles may be specified directly, or based on various parameters, e.g., based on a function of the signal and an ideal modulated signal. For example, the function of the signal and the ideal modulated signal may include one or more of: an error vector magnitude of the signal relative to the ideal modulated signal, phase error of the signal relative to the ideal modulated signal, I error of the signal relative to the ideal modulated signal, Q error of the signal relative to the ideal modulated signal, magnitude error of the signal relative to the ideal modulated signal, a function of I error and Q error of the signal relative to the ideal modulated signal, a function of magnitude error and phase error of the signal relative to the ideal modulated signal, and a random function, among others. For example, in one embodiment, if the user specifies “random” plot colors, a different (e.g., randomly determined) color may be used for each overlaid segment in the diagram.

As noted above, it may be useful to include auxiliary information in the 3D eye diagram, thus, in one embodiment, specifying the one or more attributes may include specifying display of highlight points for symbol timing, and/or display of additional points for ideal symbol locations, described above.

In one embodiment, specifying the one or more view parameters may include specifying stereoscopic display of the 3D eye diagram. For example, if the computer system 82 supports one or more stereoscopic display technologies, such as, for example, color or polarization based viewing glasses, stereoscopic display screens, etc., the user may specify which technology is to be used, upon which the appropriate stereoscopic diagram data may be generated and displayed.

In one embodiment, specifying the one or more attributes may include specifying one or more display devices for displaying the 3D eye diagram. For example, the user may specify a computer monitor, an instrument display, a cellular telephone display, a personal digital assistant (PDA) display, a virtual reality (VR) display, a true 3D display device, i.e., a volumetric display device, and/or a television display, among others.

Other aspects of the 3D eye diagram display may also be specified. For example, in one embodiment, the user may specify axis assignments for the 3D eye diagram. In other words, the user may specify which variables are associated with each axis of the diagram. For example, in one embodiment, I and Q may be specified as dependent variables and time as an independent variable. In another embodiment, real and imaginary portions of the signal data may be specified as dependent variables and time as an independent variable. In yet another embodiment, electric field strength and magnetic field strength may be specified as dependent variables and time as an independent variable. Other axis assignments are also contemplated.

As noted above, in a preferred embodiment, a projection of the 3D eye diagram may be specified to generate a 2D diagram. For example, in one embodiment, a projection may be specified to generate a 2D eye diagram, such as a 2D In-Phase (I) eye diagram, or a 2D Quadrature (Q) eye diagram. In another embodiment, a projection may be specified (e.g., onto the I-Q plane) to generate a 2D constellation diagram (I vs. Q). In one example GUI, buttons may be provided in a Views section of the panel for these projections, e.g., buttons labeled “Constellation”, “I-Eye”, and “Q-Eye”. A display area may be included for displaying the 3D eye diagram (and projections or derivative diagrams from the 3D eye diagram).

Controls may be provided for specifying other aspects of the 3D eye diagram and its creation. For example, one or more controls may be provided for specifying hardware attributes related to the generation of the 3D eye diagram, such as, for example, down converter device number, digitizer resource name, carrier frequency, and radio frequency signal analyzer (RFSA) reference level, among others.

In one embodiment, controls may be provided for specifying attributes such as, for example, the number of symbols in the diagram (e.g., 200), the symbol rate in Hz (e.g., 100.00 kHz), transmit filter (e.g., “Root Raised Cos”), and transmit filter alpha value (e.g., 0.50). Additional attributes which may be specified according to one embodiment include “eye length”, i.e., the time length of the segments as an integer multiple of the symbol period, modulation error ratio in decibels, and bandwidth in Hz.

In one embodiment, the GUI may also allow the user to specify various aspects of the signal, including, for example, the signal type, e.g., QPSK, π/4 DQPSK, QAM, etc., and PSK system parameters, such as samples per second, PSK type, optional differential PSK, MPSK, and so forth. In one embodiment, an autoscale option may be provided for autoscaling the plot. As noted above, the attributes which may be specified using the example GUI are meant to be exemplary only, and it should be noted that in other embodiments, any other attributes related to signal analysis and display may also be specified.

In various embodiments, the above methods and tools may be implemented in different ways, e.g., using text based and/or graphical programming languages, among others. For example, in one embodiment, program elements may be provided for including the 3D eye diagram functionality in an application, e.g., in the form of a toolkit or equivalent. For example, in one embodiment, the toolkit may include graphical program elements that may be used to implement and invoke the above-described functionality in a graphical program, such as a LabVIEW graphical program developed under the LabVIEW graphical programming system provided by National Instruments Corporation. It should be noted, however, that in other embodiments, the 3D eye diagram functionality may be implemented and/or invoked in other types of programs, such as text-based programs, e.g., in C, C++, or JAVA, or in other types of graphical programs. As mentioned above, in some embodiments, some or all of the functionality may be implemented in hardware, e.g., may be deployed on a programmable hardware element, such as an FPGA.

Thus, in various embodiments, the system and method operates to display and optionally analyze signals using a 3D eye diagram. Such analysis may be applicable in a variety of fields, including hardware testing and diagnostics, manufacturing, monitoring, quality control, and telecommunications, among others.

### BRIEF DESCRIPTION OF THE DRAWINGS

A better understanding of the present invention can be obtained when the following detailed description of the preferred embodiment is considered in conjunction with the following drawings, in which:

FIG. 1 illustrates an I vs. time diagram, according to the prior art;

FIG. 2 illustrates an I vs. Q vs. time diagram, according to the prior art;

FIG. 3 illustrates an I vs. Q diagram, according to the prior art;

FIG. 4 illustrates a constellation diagram, according to the prior art;

FIG. 5 illustrates an eye diagram, according to the prior art;

FIG. 6 illustrates a trellis diagram, according to the prior art;

FIG. 7A illustrates a computer-implemented signal analysis system, according to one embodiment;

FIG. 7B illustrates a networked computer-implemented signal analysis system, according to one embodiment;

FIG. 7C illustrates a signal analysis system, including various instruments, according to one embodiment;

FIG. 8 is an exemplary block diagram of the computer systems of FIGS. 7A-7C;

FIG. 9 is a flowchart diagram illustrating one embodiment of a method for displaying and analyzing signals;

FIG. 10 illustrates one embodiment of a 3D eye diagram;

FIGS. 11 and 12 illustrate embodiments of 2D projections of a 3D eye diagram;

FIG. 13 illustrates ideal symbol locations in a 3D eye diagram, according to one embodiment;

FIG. 14 illustrates a constellation diagram of a π/4 DQPSK signal, according to the prior art;

FIG. 15 illustrates a 2D eye diagram of the π/4 DQPSK signal of FIG. 14, according to the prior art;

FIG. 16 illustrates a 3D eye diagram of the π/4 DQPSK signal of FIGS. 14 and 15, according to one embodiment;

FIG. 17 illustrates one embodiment of a GUI for creating and displaying a 3D eye diagram;

FIG. 18 illustrates a 3D eye diagram control for a graphical program front panel, according to one embodiment;

FIG. 19 illustrates graphical program code corresponding to the front panel of FIG. 18; and

FIG. 20 illustrates one embodiment of inputs for a 3D eye diagram graphical program node, according to one embodiment.

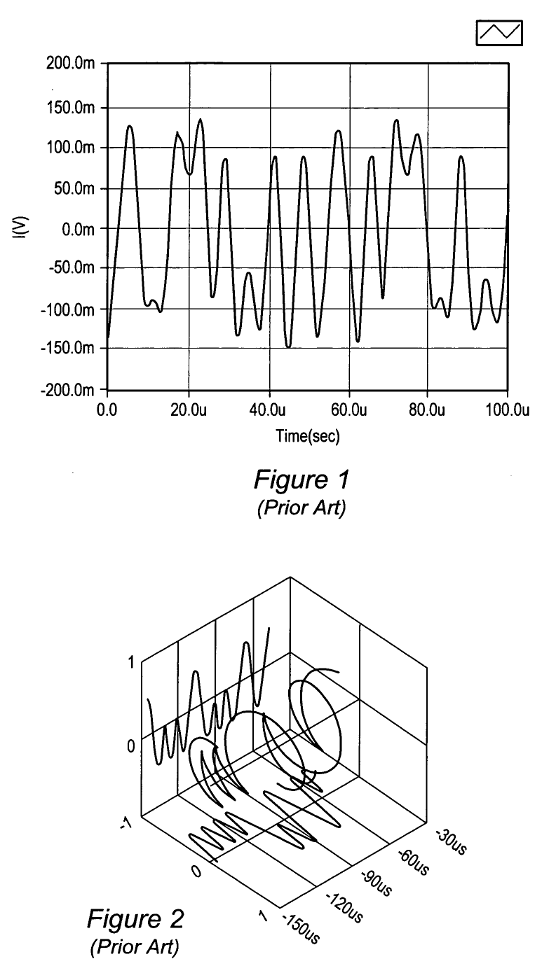

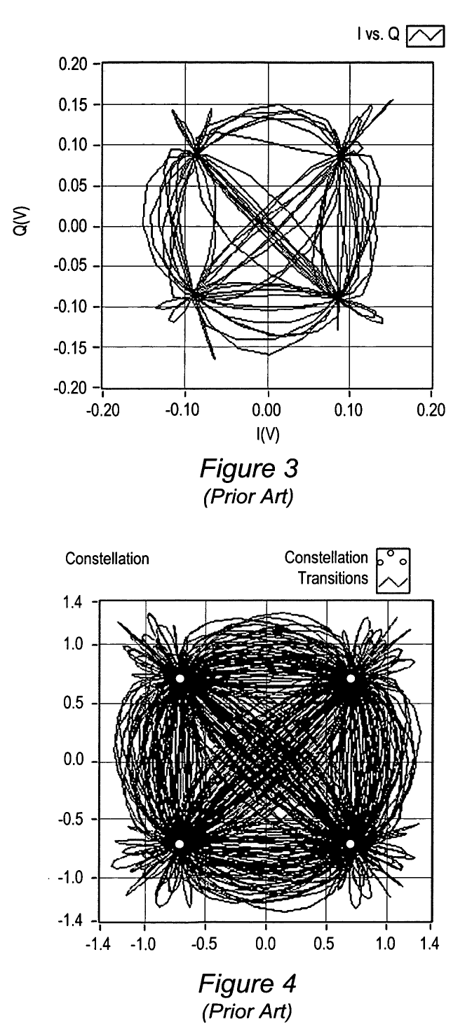

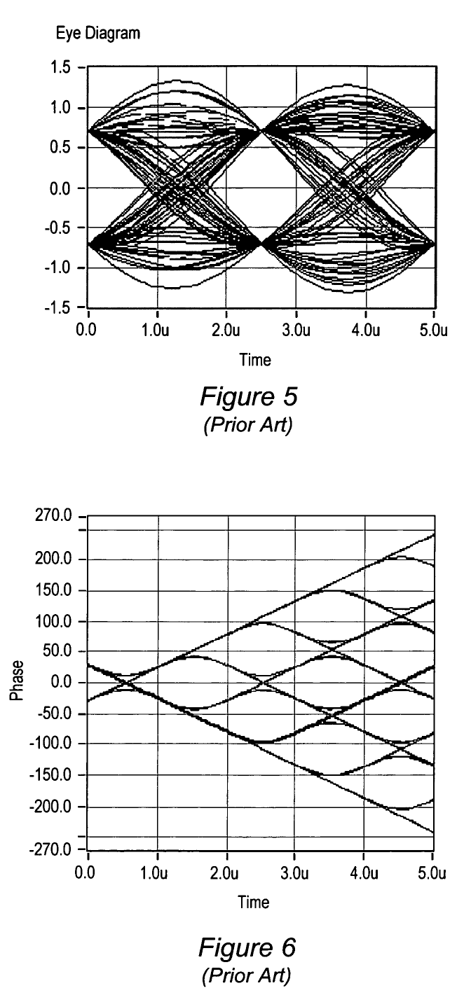

While the invention is susceptible to various modifications and alternative forms specific embodiments are shown by way of example in the drawings and are herein described in detail. It should be understood, however, that drawings and detailed description thereto are not intended to limit the invention to the particular form disclosed. But on the contrary the invention is to cover all modifications, equivalents and alternatives falling within the spirit and scope of the present invention as defined by the appended claims.

### DETAILED DESCRIPTION OF THE EMBODIMENTS

### INCORPORATION BY REFERENCE

The following references are hereby incorporated by reference in their entirety as though fully and completely set forth herein:

U.S. Pat. No. 6,377,260 titled “Method of Displaying Real and Imaginary Components of a Waveform” filed Jan. 24, 2000.

U.S. Pat. No. 4,914,568 titled “Graphical System for Modeling a Process and Associated Method,” issued on Apr. 3, 1990.

Terms

The following is a glossary of terms used in the present application:

Memory Medium—Any of various types of memory devices or storage devices. The term “memory medium” is intended to include an installation medium, e.g., a CD-ROM, floppy disks 104, or tape device; a computer system memory or random access memory such as DRAM, DDR RAM, SRAM, EDO RAM, Rambus RAM, etc.; or a non-volatile memory such as a magnetic media, e.g., a hard drive, or optical storage. The memory medium may comprise other types of memory as well, or combinations thereof. In addition, the memory medium may be located in a first computer in which the programs are executed, or may be located in a second different computer which connects to the first computer over a network, such as the Internet. In the latter instance, the second computer may provide program instructions to the first computer for execution. The term “memory medium” may include two or more memory mediums which may reside in different locations, e.g., in different computers that are connected over a network.

Carrier Medium—a memory medium as described above, as well as signals such as electrical, electromagnetic, or digital signals, conveyed via a communication medium such as a bus, network and/or a wireless link.

Programmable Hardware Element—includes various types of programmable hardware, reconfigurable hardware, programmable logic, or field-programmable devices (FPDs), such as one or more FPGAs (Field Programmable Gate Arrays), or one or more PLDs (Programmable Logic Devices), such as one or more Simple PLDs (SPLDs) or one or more Complex PLDs (CPLDs), or other types of programmable hardware. A programmable hardware element may also be referred to as “reconfigurable logic”.

Medium—includes one or more of a memory medium, carrier medium, and/or programmable hardware element; encompasses various types of mediums that can either store program instructions/data structures or can be configured with a hardware configuration program. For example, a medium that is “configured to perform a function or implement a software object” may be 1) a memory medium or carrier medium that stores program instructions, such that the program instructions are executable by a processor to perform the function or implement the software object; 2) a medium carrying signals that are involved with performing the function or implementing the software object; and/or 3) a programmable hardware element configured with a hardware configuration program to perform the function or implement the software object.

Program—the term “program” is intended to have the full breadth of its ordinary meaning. The term “program” includes 1) a software program which may be stored in a memory and is executable by a processor or 2) a hardware configuration program useable for configuring a programmable hardware element.

Software Program—the term “software program” is intended to have the full breadth of its ordinary meaning, and includes any type of program instructions, code, script and/or data, or combinations thereof, that may be stored in a memory medium and executed by a processor. Exemplary software programs include programs written in text-based programming languages, such as C, C++, Pascal, Fortran, Cobol, Java, assembly language, etc.; graphical programs (programs written in graphical programming languages); assembly language programs; programs that have been compiled to machine language; scripts; and other types of executable software. A software program may comprise two or more software programs that interoperate in some manner.

Hardware Configuration Program—a program, e.g., a netlist or bit file, that can be used to program or configure a programmable hardware element.

Graphical Program—A program comprising a plurality of interconnected nodes or icons, wherein the plurality of interconnected nodes or icons visually indicate functionality of the program.

The following provides examples of various aspects of graphical programs. The following examples and discussion are not intended to limit the above definition of graphical program, but rather provide examples of what the term “graphical program” encompasses:

The nodes in a graphical program may be connected in one or more of a data flow, control flow, and/or execution flow format. The nodes may also be connected in a “signal flow” format, which is a subset of data flow.

Exemplary graphical program development environments which may be used to create graphical programs include LabVIEW, DasyLab, DiaDem and Matrixx/SystemBuild from National Instruments, Simulink from the MathWorks, VEE from Agilent, WiT from Coreco, Vision Program Manager from PPT Vision, SoftWIRE from Measurement Computing, Sanscript from Northwoods Software, Khoros from Khoral Research, SnapMaster from HEM Data, VisSim from Visual Solutions, ObjectBench by SES (Scientific and Engineering Software), and VisiDAQ from Advantech, among others.

The term “graphical program” includes models or block diagrams created in graphical modeling environments, wherein the model or block diagram comprises interconnected nodes or icons that visually indicate operation of the model or block diagram; exemplary graphical modeling environments include Simulink, SystemBuild, VisSim, Hypersignal Block Diagram, etc.

A graphical program may be represented in the memory of the computer system as data structures and/or program instructions. The graphical program, e.g., these data structures and/or program instructions, may be compiled or interpreted to produce machine language that accomplishes the desired method or process as shown in the graphical program.

Input data to a graphical program may be received from any of various sources, such as from a device, unit under test, a process being measured or controlled, another computer program, a database, or from a file. Also, a user may input data to a graphical program or virtual instrument using a graphical user interface, e.g., a front panel.

A graphical program may optionally have a GUI associated with the graphical program. In this case, the plurality of interconnected nodes are often referred to as the block diagram portion of the graphical program.

Node—In the context of a graphical program, an element that may be included in a graphical program. A node may have an associated icon that represents the node in the graphical program, as well as underlying code or data that implements functionality of the node. Exemplary nodes include function nodes, terminal nodes, structure nodes, etc. Nodes may be connected together in a graphical program by connection icons or wires.

Data Flow Graphical Program (or Data Flow Diagram)—A graphical program or diagram comprising a plurality of interconnected nodes, wherein the connections between the nodes indicate that data produced by one node is used by another node.

Graphical User Interface—this term is intended to have the full breadth of its ordinary meaning. The term “Graphical User Interface” is often abbreviated to “GUI”. A GUI may comprise only one or more input GUI elements, only one or more output GUI elements, or both input and output GUI elements.

The following provides examples of various aspects of GUIs. The following examples and discussion are not intended to limit the ordinary meaning of GUI, but rather provide examples of what the term “graphical user interface” encompasses:

A GUI may comprise a single window having one or more GUI Elements, or may comprise a plurality of individual GUI Elements (or individual windows each having one or more GUI Elements), wherein the individual GUI Elements or windows may optionally be tiled together.

A GUI may be associated with a graphical program. In this instance, various mechanisms may be used to connect GUI Elements in the GUI with nodes in the graphical program. For example, when Input Controls and Output Indicators are created in the GUI, corresponding nodes (e.g., terminals) may be automatically created in the graphical program or block diagram. Alternatively, the user can place terminal nodes in the block diagram which may cause the display of corresponding GUI Elements front panel objects in the GUI, either at edit time or later at run time. As another example, the GUI may comprise GUI Elements embedded in the block diagram portion of the graphical program.

Front Panel—A Graphical User Interface that includes input controls and output indicators, and which enables a user to interactively control or manipulate the input being provided to a program, and view output of the program, while the program is executing.

A front panel is a type of GUI. A front panel may be associated with a graphical program as described above.

In an instrumentation application, the front panel can be analogized to the front panel of an instrument. In an industrial automation application the front panel can be analogized to the MMI (Man Machine Interface) of a device. The user may adjust the controls on the front panel to affect the input and view the output on the respective indicators.

Graphical User Interface Element—an element of a graphical user interface, such as for providing input or displaying output. Exemplary graphical user interface elements comprise input controls and output indicators.

Input Control—a graphical user interface element for providing user input to a program. Exemplary input controls comprise dials, knobs, sliders, input text boxes, etc.

Output Indicator—a graphical user interface element for displaying output from a program. Exemplary output indicators include charts, graphs, gauges, output text boxes, numeric displays, etc. An output indicator is sometimes referred to as an “output control”.

Computer System—any of various types of computing or processing systems, including a personal computer system (PC), mainframe computer system, workstation, network appliance, Internet appliance, personal digital assistant (PDA), television system, grid computing system, or other device or combinations of devices. In general, the term “computer system” can be broadly defined to encompass any device (or combination of devices) having at least one processor that executes instructions from a memory medium.

Measurement Device—includes instruments, data acquisition devices, smart sensors, and any of various types of devices that are operable to acquire and/or store data. A measurement device may also optionally be further operable to analyze or process the acquired or stored data. Examples of a measurement device include an instrument, such as a traditional stand-alone “box” instrument, a computer-based instrument (instrument on a card) or external instrument, a data acquisition card, a device external to a computer that operates similarly to a data acquisition card, a smart sensor, one or more DAQ or measurement cards or modules in a chassis, an image acquisition device, such as an image acquisition (or machine vision) card (also called a video capture board) or smart camera, a motion control device, a robot having machine vision, and other similar types of devices. Exemplary “stand-alone” instruments include oscilloscopes, multimeters, signal analyzers, arbitrary waveform generators, spectroscopes, and similar measurement, test, or automation instruments.

A measurement device may be further operable to perform control functions, e.g., in response to analysis of the acquired or stored data. For example, the measurement device may send a control signal to an external system, such as a motion control system or to a sensor, in response to particular data. A measurement device may also be operable to perform automation functions, i.e., may receive and analyze data, and issue automation control signals in response.

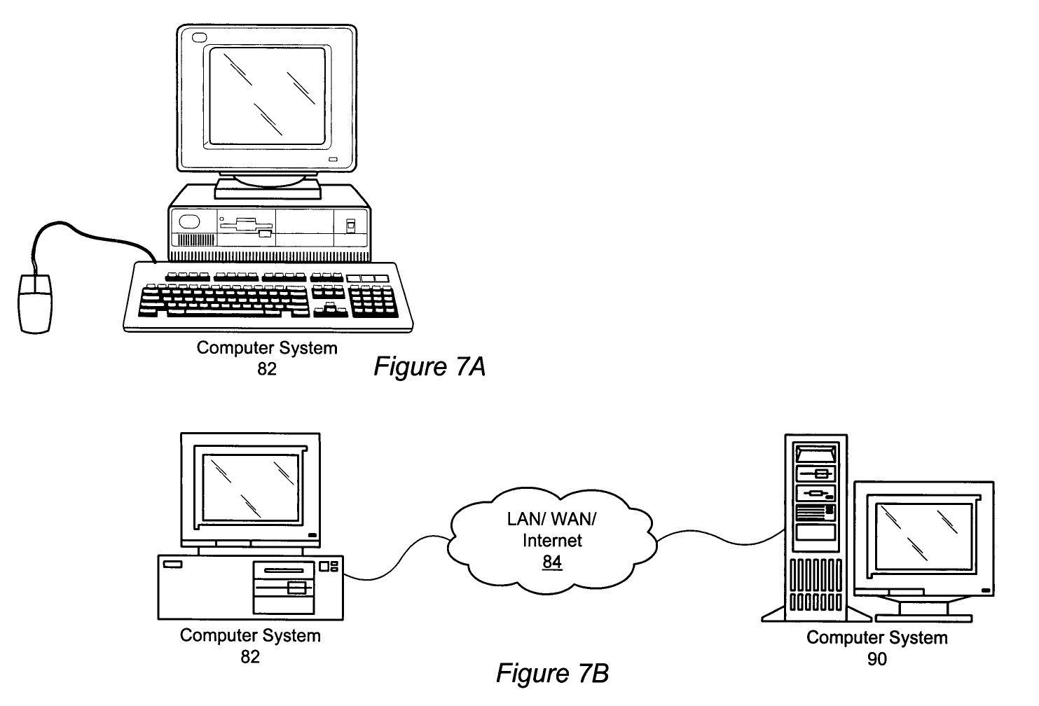

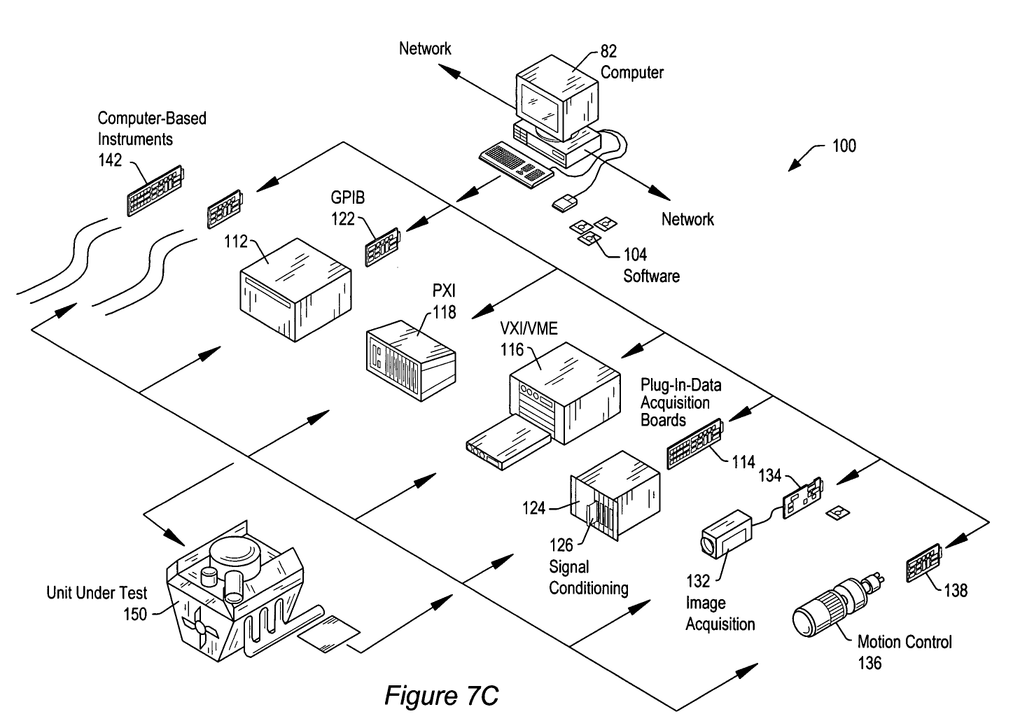

FIGS. 7A-7C—Signal Analysis Systems

FIGS. 7A-7C illustrate signal analysis systems which may be operable to perform signal analysis, according to various embodiments of the present invention. As FIG. 7A illustrates, the signal analysis system may include a computer system 82, where the computer system 82 may comprise one or more processors, a memory medium, display, an input device or mechanism, such as a keyboard or mouse, and any other components necessary for a computer system.

The signal analysis system may be operable to receive signals from a signal source and generate signal data from the signals. Alternatively, the signal analysis system may generate the signals internally and produce signal data corresponding to the generated signals.

In one embodiment, the computer analysis system may include data acquisition (DAQ) and/or processing hardware, such as a DAQ card (e.g., from National Instruments Corporation) installed in the computer system 82, or an external DAQ device coupled to the computer system 82. The DAQ hardware may be operable to receive signals from a signal source, convert the signals into digital signal data, and send the signal data to the memory medium of the computer system 82. In one embodiment, the computer system 82 may also include an analog down converter (or be coupled to an external analog down converter) operable to receive the signal from a signal source, and to convert the signal to a lower frequency domain. The DAQ card may then receive the converted signal from the converter and digitize the signal to produce the signal data.

The computer system 82 preferably includes one or more software programs executable to process and/or analyze the received signal data, and to display the processed signal data in a 3D eye diagram. The software programs may optionally be operable to analyze the 3D eye diagram and thereby produce signal analysis results characterizing one or more aspects of the signal. The software programs may be stored in the memory medium of the computer system 82.

The term “memory medium” is intended to include various types of memory, including an installation medium, e.g., a CD-ROM, or floppy disks, a computer system memory such as DRAM, SRAM, EDO RAM, Rambus RAM, etc, or a non-volatile memory such as a magnetic medium, e.g., a hard drive, or optical storage. The memory medium may comprise other types of memory as well, or combinations thereof. In addition, the memory medium may be located in a first computer in which the programs are executed, or may be located in a second different computer which connects to the first computer over a network. In the latter instance, the second computer may provide the program instructions to the first computer for execution. Also the computer system 82 may take various forms, including a personal computer system, mainframe computer system, workstation, network appliance, Internet appliance, personal digital assistant (PDA), television system or other device. In general, the term “computer system” can be broadly defined to encompass any device having a processor which executes instructions from a memory medium.

The software program(s) may be implemented in any of various ways, including procedure-based techniques, component-based techniques, graphical programming techniques, and/or object-oriented techniques, among others. For example, the software program may be implemented using ActiveX controls, C++ objects, Java Beans, Microsoft Foundation Classes (MFC), or other technologies or methodologies, as desired. A CPU, such as the host CPU, executing code and data from the memory medium comprises a means for performing signal analysis according to the methods described below.

FIG. 7B illustrates a system including first computer system 82 coupled to a second computer system 90. The computer system 82 may be connected through a network 84 (or a computer bus) to the second computer system 90. The computer systems 82 and 90 may each be any of various types, as desired. The network 84 can also be any of various types, including a LAN (local area network), WAN (wide area network), the Internet, or an Intranet, among others. The computer systems 82 and 90 may execute programs according to embodiments of the present invention, e.g., text and/or graphical programs, in a distributed fashion. For example, where a program is a graphical program, computer 82 may execute a first portion of the block diagram of a graphical program and computer system 90 may execute a second portion of the block diagram of the graphical program. As another example, computer 82 may display the graphical user interface (GUI) of a graphical program and computer system 90 may execute the block diagram of the graphical program. Of course, text-based programs may also be executed in this manner.

In one embodiment, the signal may be received by the second computer system 90 and converted and/or digitized to generate the signal data, which may then be transmitted over the network 84 to computer system 82 for processing and display in the 3D eye diagram. In another embodiment, previously acquired signal data may be stored on the second computer system 90, and transferred to computer system 82 for processing and display.

In one embodiment, the graphical user interface may be displayed on a display device of the computer system 82, and the program may execute on a device 190 connected to the computer system 82. The device 190 may include a programmable hardware element and/or may include a processor and memory medium which may execute a real time operating system. In one embodiment, the program may be downloaded and executed on the device 190. For example, an application development environment with which the program is associated may provide support for downloading a program for execution on the device in a real time system.

Other distributions of the signal analysis functionality are also contemplated, including, for example, implementing the signal analysis system using grid computing techniques, as are well known to those skilled in the art.

FIG. 7C illustrates an exemplary analysis system which may implement embodiments of the invention. The system comprises host computer 82 which connects to one or more instruments. As mentioned above, the host computer 82 may comprise a CPU, a display screen, memory, and one or more input devices such as a mouse or keyboard as shown. The computer 82 may operate with the one or more instruments to analyze, measure or control a unit under test (UUT) or process 150. For example, the host computer may send test communication signals to the UUT (e.g., a communication device), and may acquire (e.g., via DAQ board 114) resultant signals from the UUT. The host computer may then execute software to process and display the resultant signals to determine performance or design characteristics of the UUT.

The one or more instruments may include a GPIB instrument 112 and associated GPIB interface card 122, a data acquisition board 114 and associated signal conditioning circuitry 124, a VXI instrument 116, a PXI instrument 118, a video device or camera 132 and associated image acquisition (or machine vision) card 134, a motion control device 136 and associated motion control interface card 138, and/or one or more computer based instrument cards 142, among other types of devices. The computer system may couple to and operate with one or more of these instruments. The instruments may be coupled to a unit under test (UUT) or process 150, or may be coupled to receive field signals, typically generated by transducers. The system 100 may be used in a data acquisition and control application, in a test and measurement application, an image processing or machine vision application, a process control application, a man-machine interface application, a simulation application, or a hardware-in-the-loop validation application, among others.

Exemplary Systems

Embodiments of the present invention may be involved with performing test and/or measurement functions; controlling and/or modeling instrumentation or industrial automation hardware; modeling and simulation functions, e.g., modeling or simulating a device or product being developed or tested, etc. Exemplary test applications where the program or programs may be used include hardware-in-the-loop testing and rapid control prototyping, among others.

However, it is noted that the present invention can be used for a plethora of applications and is not limited to the above applications. In other words, applications discussed in the present description are exemplary only, and the present invention may be used in any of various types of systems. Thus, the system and method of the present invention is operable to be used in any of various types of applications, including the testing and/or control of other types of devices such as multimedia devices, video devices, audio devices, telephony devices, Internet devices, etc., as well as general purpose software applications such as network control, network monitoring, etc.

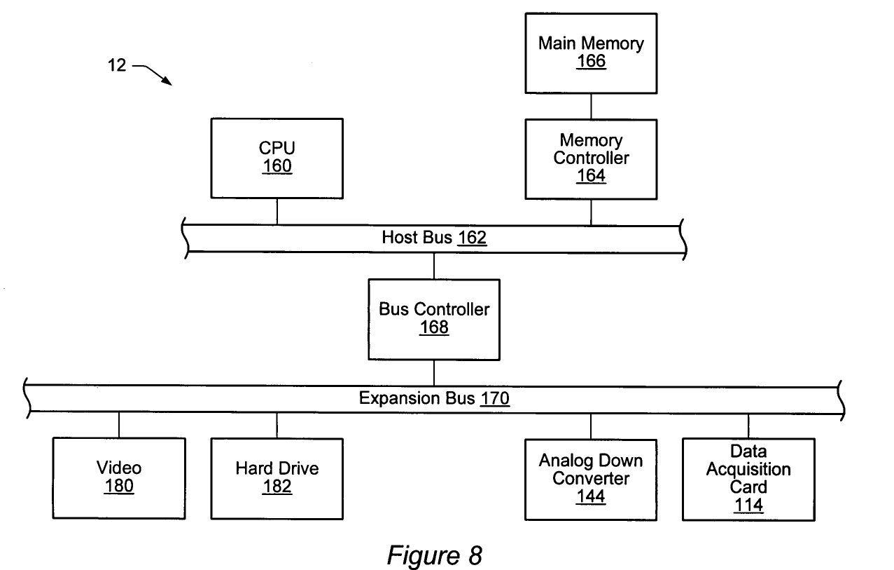

FIG. 8—Block Diagram of Computer System

FIG. 8 is a block diagram representing one embodiment of the computer system 82 and/or 90 illustrated in FIGS. 7A-7C. It is noted that any type of computer system configuration or architecture can be used as desired, and FIG. 8 illustrates a representative PC embodiment. It is also noted that the computer system may be a general purpose computer system, a computer implemented on a card installed in a chassis, or other types of embodiments. Elements of a computer not necessary to understand the present description have been omitted for simplicity.

The computer may include at least one central processing unit or CPU (processor) 160 which is coupled to a processor or host bus 162. The CPU 160 may be any of various types, including an x86 processor, e.g., a Pentium class, a PowerPC processor, a CPU from the SPARC family of RISC processors, as well as others. A memory medium, typically comprising RAM and referred to as main memory, 166 is coupled to the host bus 162 by means of memory controller 164. The main memory 166 may store one or more programs operable to implement various embodiments of the present invention. The main memory may also store operating system software, as well as other software for operation of the computer system.

The host bus 162 may be coupled to an expansion or input/output bus 170 by means of a bus controller 168 or bus bridge logic. The expansion bus 170 may be the PCI (Peripheral Component Interconnect) expansion bus, although other bus types can be used. The expansion bus 170 includes slots for various devices such as described above. The computer 82 further comprises a video display subsystem 180 and hard drive 182 coupled to the expansion bus 170.

As shown, a DAQ device 114 may also be connected to the computer, e.g., in the form of a DAQ board installed in the computer system 82, and may be operate to acquire signal data for processing by the computer system 82. As FIG. 8 also shows, in one embodiment, an analog down converter 144 may also be coupled to the computer 82, e.g., also in the form of a board installed in the computer system 82 (although standalone devices are also contemplated). The analog down converter 144 may operate to receive a signal from an external source, e.g., a WUT 150 as described above, an RF signal analyzer, etc., and to convert the received signal, shifting the frequency domain of the signal, e.g., from a radio frequency (RF) signal to an intermediate frequency (IR) signal. The DAQ device 114 may then receive the converted signal from the analog down converter 144, and may operate to digitize the converted signal and transmit the signal to the host computer 82, e.g., for storage in the memory medium and/or for processing, display, and/or analysis.

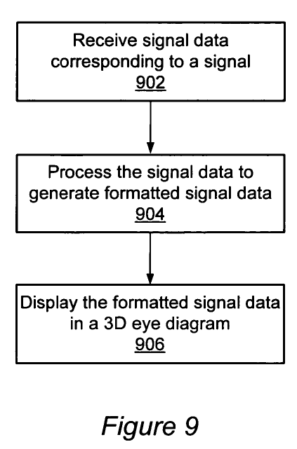

FIG. 9—Method for Displaying and Analyzing Signals

FIG. 9 is a high-level flowchart diagram of a method for displaying and analyzing signals, according to one embodiment. It should be noted that in various embodiments, some of the steps shown may be performed concurrently, in a different order than shown, or omitted. Additional steps may also be performed as desired.

As FIG. 9 shows, in 902, signal data may be received, where the signal data corresponds to a signal. The signal may be any type of signal amenable to analysis with an eye diagram. For example, the signal may comprise digital and/or analog signals. In a preferred embodiment, the signal comprises a communications signal. In one embodiment, the signal may comprise an optical communications signal, e.g., for testing optical communications components and devices.

The signal data may be received in a variety of ways. For example, in one embodiment, the signal data may have been previously received or generated, and stored on the host computer system 82, or on a second computer system 90 coupled to the host system, and so receiving the signal data may simply include retrieving the signal data from memory. In one embodiment, the signal data may be received from a data acquisition device, e.g., from DAQ board 114. Thus, receiving the signal data may include receiving the signal data from a storage medium, e.g., of the host system 82 or a memory medium coupled to the host system (e.g., a memory medium of computer system 90), and so forth, or from an external system, e.g., over a network.

As is well known in the art, a DAQ device generally receives a signal and operates to digitize the signal, thereby producing signal data, which may then be stored and/or analyzed. Thus, in one embodiment, the DAQ device 114 may receive the signal from a signal source and generate the signal data which may then be received from the DAQ device 114 (e.g., by the host computer system 82). As described above, the signal source may be any of various types of signal source. In a preferred embodiment, the signal source is a UUT (unit under test), as also described above. In one embodiment, the signal may be processed before being acquired by the DAQ device 114, e.g., by a filter or other signal-conditioning device. For example, in some testing applications for high-speed communications devices, e.g., in the GHz range, the signal may need to be frequency shifted prior to acquisition by the DAQ device 114. Thus, in one embodiment, receiving the signal data from the DAQ device may include an analog down converter 144 receiving the signal and converting the signal to a frequency-shifted signal, as described above, the DAQ device 114 receiving the frequency-shifted signal from the analog down converter and generating the signal data, and receiving the generated signal data from the DAQ device 114. For example, in a preferred embodiment, the analog down converter 144 may receive the signal in a radio frequency (RF) range, and down convert the RF signal to an intermediate frequency (IR) range, which may then be received and digitized by the DAQ device 114.

In 904, the received signal data may be processed to generate formatted signal data. More specifically, the received signal data may be processed or otherwise formatted for display in a 3D eye diagram. In a preferred embodiment, processing the received signal data may include segmenting the signal data based on a specified period, e.g., the symbol rate of the signal, to generate a plurality of segments. In one embodiment, each segment may comprise an integer number of symbols. In preferred embodiments, each segment comprises a single symbol.

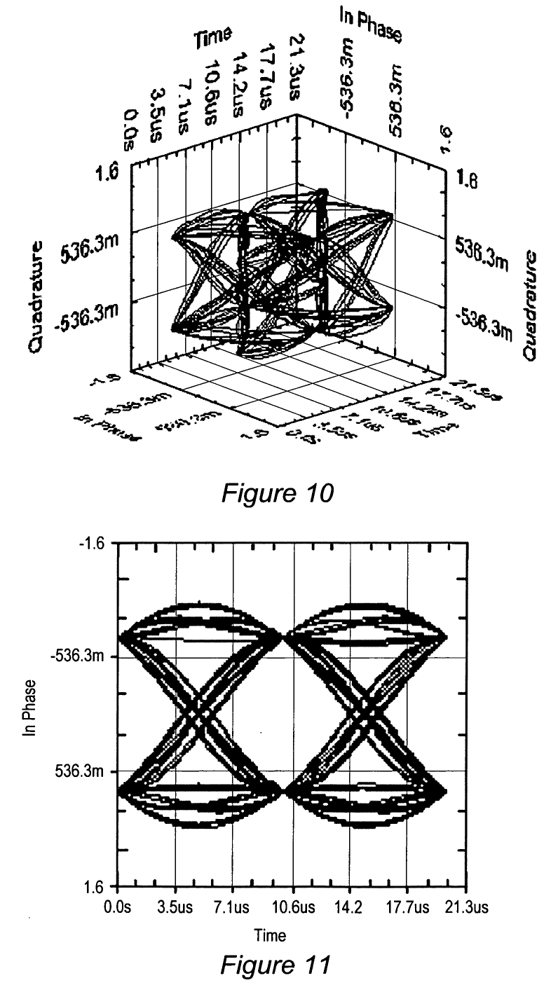

Finally, in 906, the formatted signal data may be displayed in a 3D eye diagram, where the 3D eye diagram is usable to analyze the signal. For example, the formatted signal data may be displayed in the 3D eye diagram by plotting the segments in an overlaid manner. In one embodiment, the method may optionally include analyzing the 3D eye diagram to generate signal analysis results, and outputting the signal analysis results, e.g., to one or more of: a display device, a storage medium, and/or an external system over a network, among others. As is well known to those skilled in the art, the signal analysis results may include one or more of rise time, fall time, jitter RMS (root mean square), jitter pp, period, frequency, positive/negative pulse width, duty cycle, duty cycle distortion, delta time, extinction ratio, average power, crossing percentage, one/zero levels, eye height, width, and amplitude, Q-factor, bit rate, opening factor, and contrast ratio, among others. Examples of 3D eye diagrams are described below with reference to FIGS. 10-13.

As noted above, in various embodiments, the above-described method may be implemented on or performed by various platforms, including, for example, computers, e.g., with one or more processors, memory, monitor, etc., as well as embedded systems, programmable hardware elements, such as FPGAs, and so forth.

FIGS. 10-13—3D Eye Diagram

FIGS. 10-13 illustrate exemplary embodiments of a 3D eye diagram, as may be generated by various embodiments of the method of FIG. 9. FIG. 10 illustrates an example 3D eye diagram, according to one embodiment. As FIG. 10 shows, the 3D eye diagram of this example plots I (In-Phase) and Q (Quadrature) vs. time. In this particular example, the signal data corresponds to a QPSK signal.

There are numerous ways the 3D eye diagram may be useful for signal analysis. For example, the 3D eye diagram may be projected onto various 2D planes to generate respective 2D diagrams. FIG. 11 illustrates a projection of the 3D eye diagram data of FIG. 10 onto the I-time plane. Note that this projection generates an I eye diagram, where I is plotted vs. time. A similar 2D eye diagram for Q may be generated by projecting the 3D eye diagram data of FIG. 10 onto the Q-time plane, where Q is plotted vs. time. Thus, the 3D eye diagram may be used, e.g., via projection, to generate standard 2D eye diagrams, whose use in signal analysis is well known in the art.

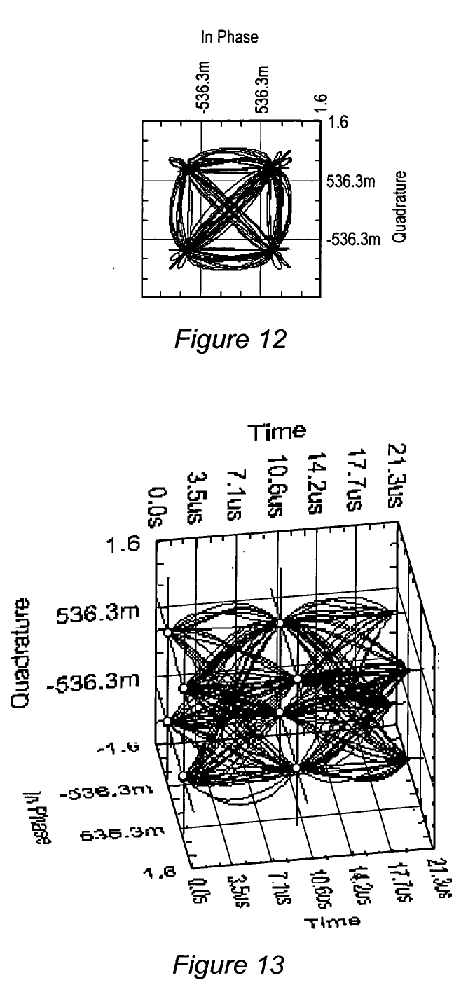

Further projections of the 3D eye diagram may also be useful. For example, FIG. 12 illustrates a projection of the 3D eye diagram data onto the I-Q plane, thereby generating an I vs. Q diagram, also referred to as a constellation plot, which is useful for signal analysis, as is also well known in the art.

In standard (2D) eye diagrams, it is sometimes useful to indicate additional information in plots. For example, lines and/or points may be added to indicate ideal symbol timing locations, i.e., computed values of communications symbol starts and stops. FIG. 13 illustrates the 3D eye diagram of FIG. 10, but with auxiliary graphical elements indicating such ideal symbol locations, where the locations are indicated with orthogonal lines that intersect at the ideal points, as well as small white points or spheres at the ideal points. In the example of FIG. 13, the QPSK signal has a symbol rate of 100,000 symbols/s, and the ideal signal locations are at 0 seconds and 10⁴ seconds, as shown. Of course, this is only one example of auxiliary information that may be added to the 3D eye diagram, and it should be noted that any other type of information may be included in the 3D eye diagram (or in plots or projections derived from the 3D eye diagram) as desired. Note that in some embodiments, the projections may be performed simply by orienting the 3D eye diagram such that the displayed image of the 3D diagram comprises the desired projection. In other words, the 3D eye diagram may be manipulated to display or generate signal data and/or relationships that may be useful in analyzing the signal.

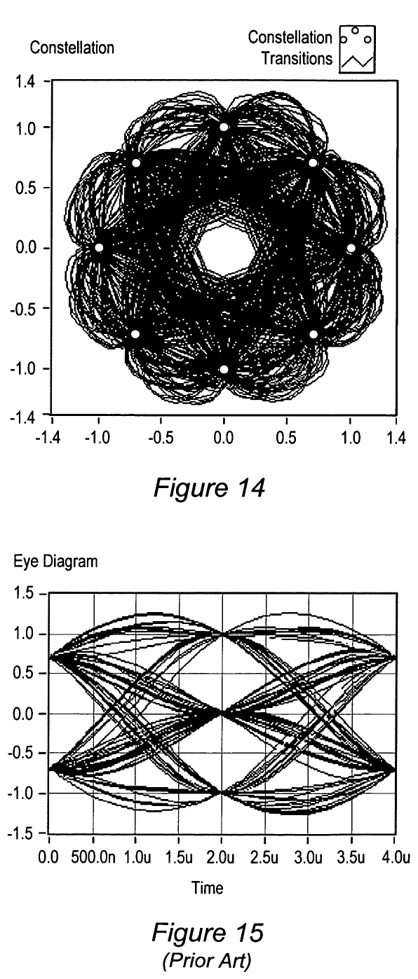

FIGS. 14-16—Example: Constellation Plot

As described above, a 3D eye diagram may include in a single plot information that would require numerous prior art signal plots. FIGS. 14-16 illustrate an advantageous use of a 3D eye diagram in the context of a constellation plot. FIG. 14 illustrates a constellation plot of a π/4 differential quadrature phase shift keyed (π/4 DQPSK) signal, according to the prior art. As is well known to those skilled in the art, in a π/4 DQPSK signal, the I and Q coordinates of the symbols rotate by π/4 radians per symbol. As FIG. 14 shows, this constellation plot indicates the symbol locations as white points in a radial configuration, referred to as a constellation. Note that although there appear to be eight points in the constellation, there are actually only four points. This is due to the fact that with each symbol, the ideal locations rotate by π/4 radians in the I-Q plane. However, this rotation is not apparent in this 2D constellation diagram.

FIG. 15 illustrates a standard 2D eye diagram for the π/4 DQPSK signal of FIG. 14. As FIG. 15 shows, this rotation (of π/4 radians) is also not readily apparent in a 2D eye diagram. In other words, although one can see from FIG. 15 that the constellation locations have changed, but it is not readily apparent that the change is due to rotation.

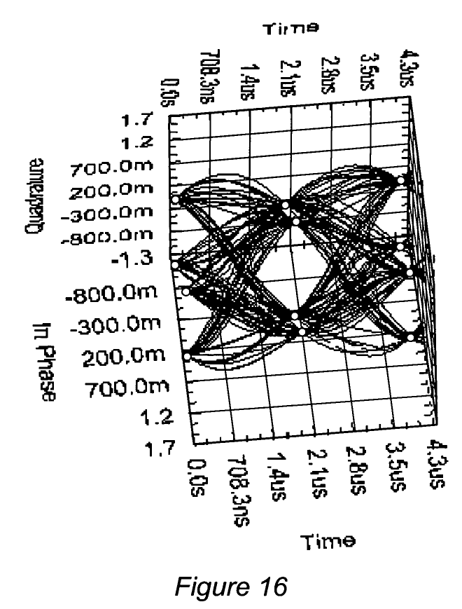

FIG. 16 illustrates one embodiment of a 3D eye diagram of the π/4 DQPSK signal of FIG. 14. As may be seen in FIG. 16, the rotation of the ideal symbol locations (indicated by white points or spheres) with each symbol is readily apparent due to the three dimensional character of the plot. The symbol location rotations may be especially clear if the user is able to manipulate the 3D plot, e.g., by changing the viewing angle.

Note that in one embodiment, the display (the 3D eye diagram) may also be used as a visual measure of the quality of a modulated signal, in that as the quality of the signal degrades, the nearest approach of the plots to the ideal symbol locations becomes progressively larger, i.e., the signal traces or plots “miss” the ideal locations by increasingly greater amounts.

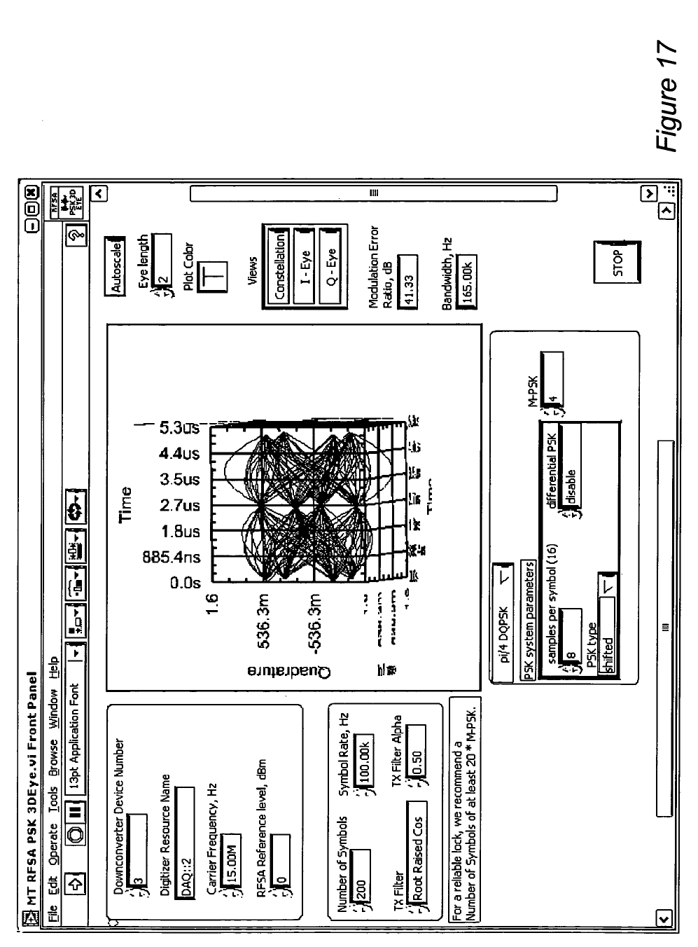

FIGS. 17-20—Graphical User Interface for 3D Eye Diagram

As noted above, the utility of a 3D eye diagram may be substantially enhanced by manipulating the diagram, e.g., by changing the view angle, projecting the diagram onto various planes, adding auxiliary information, and so forth. Thus, in one embodiment, a graphical user interface (GUI) may be provided for specifying, creating, editing, and viewing 3D eye diagrams. FIGS. 17-20 illustrate various embodiments of such a GUI or tool for 3D eye diagrams. It should be noted that the embodiments shown and described herein are intended to be exemplary only, and are not intended to limit the implementation, appearance, or functionality of the 3D eye diagram tool or GUI to any particular form.

In simple embodiments of the 3D eye diagram tool, the tool may primarily receive signal data, process the data as described above, and display the data in a 3D eye diagram, optionally allowing the user to rotate the diagram in 3D or otherwise project the diagram onto desired planes. Thus, the GUI may include a display area or panel for displaying the generated 3D eye diagram. However, in preferred embodiments, the 3D eye diagram tool may facilitate specification of many aspects of the diagram by the user. In other words, in a preferred embodiment, the method of FIG. 9, described above, may include receiving user input specifying one or more attributes of the 3D eye diagram, and displaying the 3D eye diagram in accordance with the specified attributes.

For example, in one embodiment, specifying one or more attributes may include specifying one or more view parameters for displaying the 3D eye diagram, such as, for example, a zoom factor, a rotation of the 3D eye diagram, and a translation of the 3D eye diagram, thereby specifying display of the 3D diagram. Thus, the user may specify an effective camera point of view (POV) and viewing distance (diagram size), for viewing the diagram. In various embodiments, the view parameters may be specified in different ways. For example, in one embodiment, the image may be “zoomed” using the mouse and/or keyboard. Similarly, rotations and translations may be specified using the mouse and/or keyboard. For example, in one embodiment, in one embodiment, the user may click on the diagram (e.g., on a “handle”, e.g., an axis endpoint, etc.) and, while holding the mouse key down, drag the mouse to rotate the diagram, where the direction of the mouse movement and/or the location of the diagram “handle” determines the axis of rotation. Alternatively, the user may specify an axis, then click on the diagram and, while holding the mouse key down, drag the mouse to rotate the diagram around the specified axis. In one embodiment, the user may use the mouse in combination with various keys to indicate the desired view specifications. For example, arrow keys (optionally in conjunction with other keys and/or the mouse) may be used to manipulate the diagram image. Other means of zooming, rotating and translating the diagram are also contemplated. For example, in one embodiment, respective controls, e.g., slider controls, may be provided in the GUI for modifying zoom, rotation, and/or translation of the diagram.

In one embodiment, the user may manipulate the diagram (i.e., the image of the diagram) while the data are being acquired and/or displayed. Thus, the 3D eye diagram tool may be receiving and displaying signal data while the user modifies the display (or other aspects) of the diagram, where the display is updated in (substantially) real time in accordance with the modifications or specifications.

In one embodiment, plot colors, plot line styles (e.g., line thickness, dotted, dashed, solid, etc.) and/or point color and/or styles, may be specified. For example, plot colors and/or line styles may be specified directly, or based on various parameters, e.g., based on a function of the signal and an ideal modulated signal. For example, the function of the signal and the ideal modulated signal may include one or more of: an error vector magnitude of the signal relative to the ideal modulated signal, phase error of the signal relative to the ideal modulated signal, I error of the signal relative to the ideal modulated signal, Q error of the signal relative to the ideal modulated signal, magnitude error of the signal relative to the ideal modulated signal, a function of I error and Q error of the signal relative to the ideal modulated signal, a function of magnitude error and phase error of the signal relative to the ideal modulated signal, and a random function, among others. For example, in one embodiment, if the user specifies “random” plot colors, a different (e.g., randomly determined) color may be used for each overlaid segment in the diagram.

As noted above, it may be useful to include auxiliary information in the 3D eye diagram, thus, in one embodiment, specifying the one or more attributes may include specifying display of highlight points for symbol timing, and/or display of additional points for ideal symbol locations, such as shown in FIGS. 13-16, described above. Of course, any other type of auxiliary information may also be specified, as desired.

In one embodiment, specifying the one or more view parameters may include specifying stereoscopic display of the 3D eye diagram. For example, if the computer system 82 supports one or more stereoscopic display technologies, such as, for example, color or polarization based viewing glasses, stereoscopic display screens, etc., the user may specify which technology is to be used, in response to which the appropriate stereoscopic diagram data may be generated and displayed.

In one embodiment, specifying the one or more attributes may include specifying one or more display devices for displaying the 3D eye diagram. For example, the user may specify a computer monitor, an instrument display, a cellular telephone display, a personal digital assistant (PDA) display, a virtual reality (VR) display, a true 3D display device, i.e., a volumetric display device, and/or a television display, among others.

Other aspects of the 3D eye diagram display may also be specified. For example, in one embodiment, the user may specify axis assignments for the 3D eye diagram. In other words, the user may specify which variables are associated with each axis of the diagram. For example, in one embodiment, I and Q may be specified as dependent variables and time as an independent variable. In another embodiment, real and imaginary portions of the signal data may be specified as dependent variables and time as an independent variable. In yet another embodiment, electric field strength and magnetic field strength may be specified as dependent variables and time as an independent variable. Other axis assignments are also contemplated.

As noted above, in a preferred embodiment, a projection of the 3D eye diagram may be specified to generate a 2D diagram, such as, for example, a 2D In-Phase (I) eye diagram, or a 2D Quadrature (Q) eye diagram. In another embodiment, a projection may be specified (onto the I-Q plane) to generate a 2D constellation diagram (I vs. Q). In the example GUI of FIG. 17, buttons are provided in a Views section on the right side of the panel for specifying these projections, namely, buttons labeled “Constellation”, “I-Eye”, and “Q-Eye”, as shown. As FIG. 17 shows, a display area may be included for displaying the 3D eye diagram (and projections or derivative diagrams from the 3D eye diagram).

As the example GUI of FIG. 17 also shows, controls may be provided for specifying other aspects of the 3D eye diagram and its creation. For example, as shown in the top left section of the GUI, one or more controls may be provided for specifying hardware attributes related to the generation of the 3D eye diagram, such as, for example, down converter device number, digitizer resource name, carrier frequency, and radio frequency signal analyzer (RFSA) reference level, among others.

As also shown in the embodiment of FIG. 17, controls may be provided for specifying attributes such as, for example, the number of symbols in the diagram (here set to 200), the symbol rate in Hz (100.00 kHz), transmit filter (“Root Raised Cos”), and transmit filter alpha value (0.50). Additional attributes which may be specified according to the embodiment of FIG. 17 include “eye length”, i.e., the time length of the segments as an integer multiple of the symbol period, modulation error ratio in decibels, and bandwidth in Hz.

In one embodiment, the GUI may also allow the user to specify various aspects of the signal, including, for example, the signal type, e.g., QPSK, π/4 DQPSK, QAM, etc., and PSK system parameters, such as samples per second, PSK type, optional differential PSK, M-PSK, and so forth. In one embodiment, an autoscale option may be provided for autoscaling the plot.

As noted above, the attributes which may be specified using the GUI of FIG. 17 are meant to be exemplary only, and it should be noted that in other embodiments, any other attributes related to signal analysis and display may also be specified.

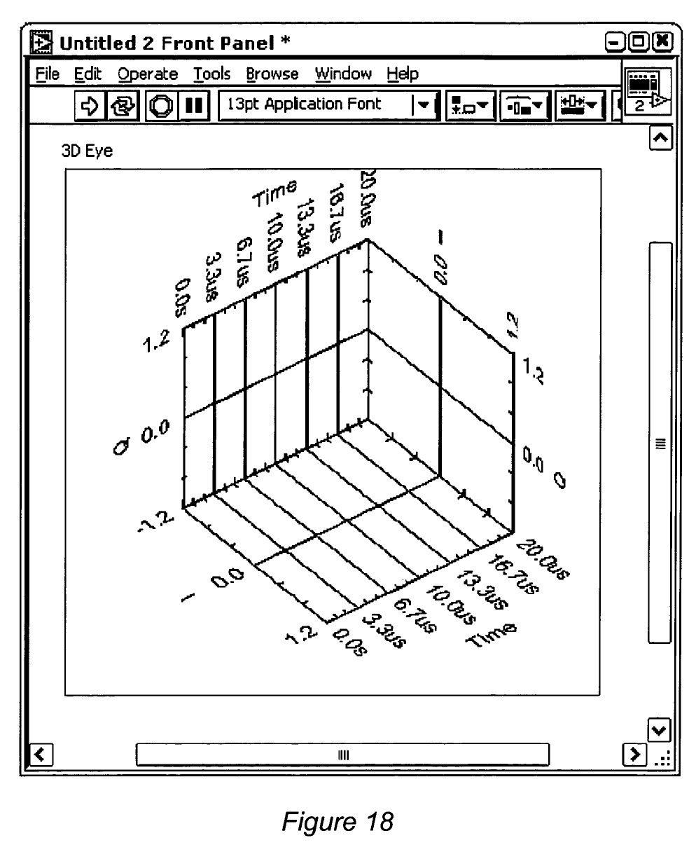

FIGS. 18-20—Example Implementation

FIGS. 18-20 illustrate various aspects of an implementation of the 3D eye diagram tool, according to one embodiment. In one embodiment, program elements may be provided for including the 3D eye diagram functionality in an application, e.g., in the form of a toolkit or equivalent. For example, in one embodiment, the toolkit may include graphical program elements that may be used to implement and invoke the above-described functionality in a graphical program, such as a LabVIEW graphical program developed under the LabVIEW graphical programming system provided by National Instruments Corporation. It should be noted, however, that in other embodiments, the 3D eye diagram functionality may be implemented and/or invoked in other types of programs, such as text-based programs, e.g., in C, C++, or JAVA, or in other types of graphical programs. Additionally, in some embodiments, the 3D eye diagram functionality may be implemented and invoked as a standalone tool, i.e., as opposed to being invoked from a program. As mentioned above, in some embodiments, some or all of the functionality may be implemented in hardware, e.g., may be deployed on a programmable hardware element, such as an FPGA.

Overview of Graphical Programming

Typically, a graphical program may be created or assembled by the user arranging on a display a plurality of nodes or icons and then interconnecting the nodes to create the graphical program. In response to the user assembling the graphical program, data structures may be created and stored which represent the graphical program. The nodes may be interconnected in one or more of a data flow, control flow, or execution flow format. The graphical program may thus comprise a plurality of interconnected nodes or icons which visually indicates the functionality of the program. The interconnected nodes or icons may be referred to as a block diagram.

As noted above, the graphical program may comprise a block diagram and may also include a user interface portion or front panel portion. The front panel may include various graphical user interface elements or front panel objects, such as user interface controls and/or indicators, that represent or display the respective input and output that will be used by the graphical program, and may include other icons which represent devices being controlled. Where the graphical program includes a user interface portion, the user may optionally assemble the user interface on the display. As one example, the user may use the LabVIEW graphical programming development environment to create the graphical program.

FIG. 18 illustrates a graphical user interface element or front panel object (i.e., a control or indicator) that may be included in a front panel of a graphical program (i.e., the user interface portion of the graphical program) for displaying a 3D eye diagram. As FIG. 18 shows, the user interface element may operate to display a 3D graph which may be used to plot the 3D eye diagram upon execution of the graphical program. For example, in one embodiment, the display portion of the GUI of FIG. 17 may be developed using the GUI element of FIG. 18.

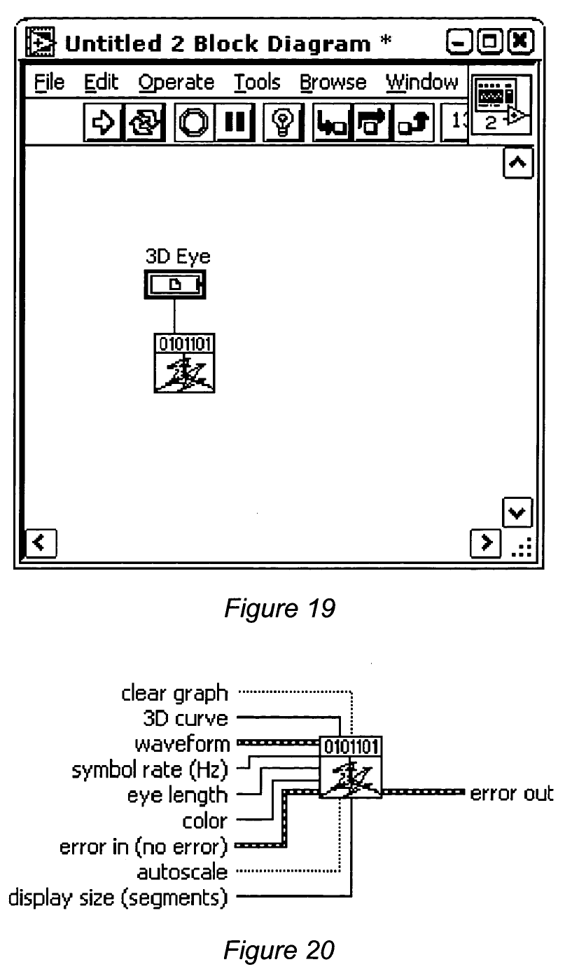

As described above, generally, a front panel GUI element (indicator or control) corresponds to a graphical program element in the block diagram of the graphical program. FIG. 19 illustrates a graphical program node (labeled “0101101”) coupled to a terminal (labeled “3D Eye”), where the terminal provides a linkage between the node and the front panel GUI element of FIG. 18. In a preferred embodiment, when the GUI element of FIG. 18 is placed on the front panel of the graphical program, the graphical program code shown in FIG. 19 is automatically placed in the block diagram of the graphical program. Of course, other nodes and graphical program elements may also be included in the graphical program as desired.

In the embodiment shown, the node includes or represents a function (e.g., via underlying code) that operates to format a modulated signal (or more properly, signal data) and provide the formatted signal data to the 3D eye terminal whereby the signal data is displayed on the 3D eye diagram of the front panel.

FIG. 20 illustrates data inputs for one embodiment of the function node of FIG. 19. As FIG. 20 shows, in this example the inputs for the node include a “clear graph” input, for specifying that the 3D eye diagram be cleared of current plots, a “3D curve” parameter for specifying a reference to a GUI element that displays the 3D diagram, e.g., a 3D graph control, an eye length parameter for specifying the time-duration or length of each symbol or segment, a color parameter for specifying plot color, an autoscale parameter for specifying autoscaling of the diagram, and a display size in segments, specifying the number of overlaid segments to plot in the 3D eye diagram. In general, the time required to plot the 3D eye diagram may increase with the number of segments plotted.

Also shown in FIG. 20 are inputs for receiving waveform data and an error in (no error) indication to the node. As FIG. 20 also shows, an error out parameter may also be included for outputting error indications from the node. It should be noted that the node of FIGS. 19 and 20 is meant to be exemplary only, and is not intended to limit the appearance or functionality of the node to any particular form or function.

In one embodiment, the node may operate to receive a complex-valued waveform, divide the waveform into segments, and display the segments as overlapping plots in the 3D graph of FIG. 18. The node may determine the segment length based on the symbol rate and eye length input parameters.

As described above, upon execution of the graphical program, the 3D graph, i.e., the GUI element of FIG. 18, preferably displays the graph with axes corresponding to the I waveform component, the Q waveform component, and time.

Thus, various embodiments of the present invention may facilitate specification, creation, and display of 3D eye diagrams for signal analysis.

Various embodiments further include receiving or storing instructions and/or data implemented in accordance with the foregoing description upon a carrier medium. Suitable carrier media include a memory medium as described above, as well as signals such as electrical, electromagnetic, or digital signals, conveyed via a communication medium such as networks and/or a wireless link.

Although the embodiments above have been described in considerable detail, numerous variations and modifications will become apparent to those skilled in the art once the above disclosure is fully appreciated. It is intended that the following claims be interpreted to embrace all such variations and modifications.

1. A medium configured for analyzing signals, wherein the medium is configured to perform:
receiving signal data corresponding to a signal;
processing the received signal data to generate formatted signal data; and
displaying the formatted signal data in a three dimensional (3D) eye diagram, wherein the 3D eye diagram is usable to analyze the signal.

2. The medium of claim 1, wherein said receiving signal data corresponding to a signal comprises:
receiving the signal data from a data acquisition (DAQ) device.

3. The medium of claim 2, wherein said receiving signal data from a data acquisition device comprises:
an analog down converter receiving the signal and converting the signal to a frequency-shifted signal;
the DAQ device receiving the frequency-shifted signal from the analog down converter and generating the signal data; and
receiving the generated signal data from the DAQ device.

4. The medium of claim 1,
wherein said processing the received signal data comprises:
segmenting the signal data based on a specified period to generate a plurality of segments; and
wherein said displaying the formatted signal data comprises:
plotting the segments in an overlaid manner.

5. The medium of claim 1, wherein the medium is further configured to perform:
receiving user input specifying one or more attributes of the 3D eye diagram; and
displaying the 3D eye diagram in accordance with the specified attributes.

6. The medium of claim 5, wherein the specifying one or more attributes comprises:
specifying one or more view parameters for said displaying the 3D eye diagram.

7. The medium of claim 6, wherein said specifying one or more view parameters comprises specifying one or more of:
a zoom factor;
a rotation of the 3D eye diagram;
a translation of the 3D eye diagram.

8. The medium of claim 6, wherein said specifying one or more view parameters comprises specifying stereoscopic display of the 3D eye diagram.

9. The medium of claim 5, wherein the specifying one or more attributes comprises:
specifying one or more display devices for said displaying the 3D eye diagram, wherein the one or more display devices comprise one or more of:
a computer monitor;
an instrument display;
a cellular telephone display;
a personal digital assistant (PDA) display;
a virtual reality (VR) display;
a television display; and
a 3D display device.

10. The medium of claim 5, wherein said specifying one or more attributes comprises specifying the one or more attributes based on a user-defined function.

11. The medium of claim 5, wherein the specifying one or more attributes comprises specifying one or more of:
plot colors; and
plot line styles.

12. The medium of claim 11, wherein said specifying one or more attributes comprises specifying the one or more attributes based on a function of the signal and an ideal modulated signal

13. The medium of claim 12, wherein said function of the signal and the ideal modulated signal comprises one or more of:
an error vector magnitude of the signal relative to the ideal modulated signal;
phase error of the signal relative to the ideal modulated signal;
I error of the signal relative to the ideal modulated signal;
Q error of the signal relative to the ideal modulated signal;
magnitude error of the signal relative to the ideal modulated signal;
a function of I error and Q error of the signal relative to the ideal modulated signal;
a function of magnitude error and phase error of the signal relative to the ideal modulated signal;
a random function.

14. The medium of claim 5, wherein the specifying one or more attributes comprises specifying one or more of:
point colors; and
point styles.

15. The medium of claim 5, wherein the specifying one or more attributes comprises specifying one or more of:
display of highlight points for symbol timing; and
display of additional points for ideal symbol locations.

16. The medium of claim 5, wherein said specifying one or more attributes comprises specifying one or more of:
axis assignments for the 3D eye diagram.

17. The medium of claim 16, wherein said specifying axis assignments for the 3D eye diagram comprises specifying one or more of:
I and Q as dependent variables and time as an independent variable;
real and imaginary portions of the signal data as dependent variables and time as an independent variable; and
electric field strength and magnetic field strength as dependent variables and time as an independent variable.

18. The medium of claim 5, wherein said specifying one or more attributes comprises:
specifying a projection of the 3D eye diagram to generate a 2D diagram.

19. The medium of claim 18, wherein 2D diagram comprises one or more of:
a 2D eye diagram; and
a 2D constellation diagram.

20. The medium of claim 19, wherein 2D eye diagram comprises one or more of:
a 2D In-Phase (I) eye diagram; and
a 2D Quadrature (Q) eye diagram.

21. The medium of claim 18, wherein said specifying a projection of the 3D eye diagram to generate a 2D diagram comprises:
specifying an orientation of the 3D eye diagram to generate the 2D diagram.

22. The medium of claim 1, wherein the signal comprises a communications signal.

23. The medium of claim 1, wherein the signal comprises an optical communications signal.

24. The medium of claim 1, wherein the signal comprises digital and/or analog signals.

25. The medium of claim 1, wherein the medium is further configured to perform:
analyzing the 3D eye diagram to generate signal analysis results.

26. The medium of claim 25, wherein the medium is further configured to perform:
outputting the signal analysis results.

27. The medium of claim 25, wherein said outputting the signal analysis results comprises outputting the signal analysis results to one or more of:
a display device;
a storage medium; and
an external system over a network.

28. The medium of claim 1, where said receiving signal data corresponding to a signal comprises:
receiving the signal data from an external system.

29. The medium of claim 1, where said receiving signal data corresponding to a signal comprises:
receiving the signal data from a storage medium.

30. The medium of claim 1, wherein the medium comprises a carrier medium.

31. The medium of claim 1, wherein the medium comprises a programmable hardware element.

32. The medium of claim 1, wherein the medium comprises a memory medium that stores program instructions which are executable by a processor to perform said receiving, said processing, and said displaying.

33. A system for analyzing signals, the system comprising:
a processor;
a memory medium coupled to the processor;
an input; and
an output;
wherein the input is operable to receive signal data corresponding to a signal; and
wherein the memory medium stores program instructions which are executable by the processor to:
receiving signal data corresponding to a signal;
processing the received signal data to generate formatted signal data; and
displaying the formatted signal data in a three dimensional (3D) eye diagram, wherein the 3D eye diagram is usable to analyze the signal.

34. A system for analyzing signals, the system comprising:
means for receiving signal data corresponding to a signal;
means for processing the received signal data to generate formatted signal data; and
means for displaying the formatted signal data in a three dimensional (3D) eye diagram, wherein the 3D eye diagram is usable to analyze the signal.
